(19) United States
(12) Patent Application Publication
(10) Pub. No.: US 2024/0348225 A1
(43) Pub. Date: Oct. 17, 2024

(54) ELECTRICAL VARIABLE CAPACITOR CIRCUIT AND SEMICONDUCTOR PROCESSING SYSTEM INCLUDING SAME

(71) Applicant: INDUSTRIAL COOPERATION FOUDATION JEONBUK NATIONAL UNIVERSITY, Jeonju-si, Jeollabuk-do (KR)

(72) Inventors: Yongsug SUH, Jeonju-si, Jeollabuk-do (KR); Juhwa MIN, Jeonju-si, Jeollabuk-do (KR)

(73) Assignee: INDUSTRIAL COOPERATION FOUDATION JEONBUK NATIONAL UNIVERSITY, Jeonju-si, Jeollabuk-do (KR)

(21) Appl. No.: 18/580,376

(22) PCT Filed: Aug. 17, 2022
(86) PCT No.: PCT/KR2022/012232

§ 371 Date: Jan. 18, 2024

(30) Foreign Application Priority Data
Aug. 17, 2021 (KR) 10-2021-0107945

(51) Int. Cl. H03H 7/38; H01J 37/32; H03H 7/01

(52) U.S. Cl. CPC H03H 7/38; H01J 37/32183; H03H 7/0115

(57) ABSTRACT

A semiconductor processing system includes: an RF power supply which generates and supplies RF power; a plasma chamber which receives the RF power from the RF power supply; and an impedance matching circuit which is arranged between the RF power supply and the plasma chamber and matches output impedance to the plasma chamber. The impedance matching circuit includes a plurality of electrical variable capacitor circuits. Each of the electrical variable capacitor circuits includes: a first node connected to one side of the RF power supply; a second node connected to the other side of the RF power supply; a variable capacitor connected to the first node; a PIN diode connected in parallel to the variable capacitor; a switch connected in series to the PIN diode; and an inductor connected in parallel to the variable capacitor and the switch.

### CROSS-REFERENCE TO PRIOR APPLICATIONS

This application is a National Stage Application of PCT International Application No. PCT/KR2022/012232 (filed on Aug. 17, 2022), which claims priority to Korean Patent Application No. 10-2021-0107945 (filed on Aug. 17, 2021), which are all hereby incorporated by reference in their entirety.

### BACKGROUND

The present invention relates to an impedance matching circuit, and more particularly, to an electrically variable capacitor applied to an impedance matching circuit and a semiconductor processing system including the same.

Recently, interest in semiconductor manufacturing processes has been increasing every year. Specifically, among semiconductor manufacturing processes, a radio frequency (RF) plasma process can be said to be a representative etching process. An etching process uses an RF plasma system composed of an RF power supply, a plasma load, and an impedance matching circuit.

The impedance matching circuit matches the impedance of a load and an input so that maximum power transmission to a plasma chamber is ensured at all times. The plasma load is a load which constantly changes depending on the type and amount of gas used in the chamber and whether plasma is generated, and to satisfy maximum power transmission, an impedance matching circuit is essentially required. In this case, a capacitor called a vacuum variable capacitor and whose capacitance is mechanically variable is used in the impedance matching circuit to match the impedance in response to the variable load. However, since the vacuum variable capacitor mechanically changes capacitance, an electrically variable capacitor which electrically changes capacitance due to a slow variable time, which accounts for 30% of the etching process, has been researched.

However, electrically variable capacitors do not reach the level of satisfying the requirements (for example, reliability, volume, efficiency, weight, the number of capacitance values, and the like) for replacing existing vacuum variable capacitors.

Accordingly, research on an electrically variable capacitor capable of satisfying the above requirements is needed.

### SUMMARY

The present invention is directed to providing an electrically variable capacitor circuit and a semiconductor processing system including the same which reduce the number of elements to save costs and reduce volume.

The present invention is directed to providing an electrically variable capacitor circuit and a semiconductor processing system including the same which reduce the number of elements to save costs and reduce volume.

In order to achieve the purpose, the present invention, the semiconductor processing system including a radio frequency (RF) power supply configured to generate and supply RF power, a plasma chamber configured to receive the RF power from the RF power supply, and an impedance matching circuit disposed between the RF power supply and the plasma chamber to match output impedance to the plasma chamber, wherein each of the impedance matching circuits includes a plurality of electrically variable capacitor circuits, and the electrically variable capacitor circuit includes a first node connected to one side of the RF power supply, a second node connected to the other side of the RF power supply, a variable capacitor connected to the first node, a PIN diode connected in parallel with the variable capacitor, a switch connected in series with the PIN diode, and an inductor connected in parallel with the variable capacitor and the switch.

Further, the plurality of electrically variable capacitor circuits may have the same structure.

In addition, the number of the plurality of electrically variable capacitor circuits may be configured to be 8 to 28.

In addition, an anode of the PIN diode may be connected to the variable capacitor, and a cathode of the PIN diode may be connected to the switch.

In addition, the cathode of the PIN diode may be connected to the variable capacitor, and the anode of the PIN diode may be connected to the switch.

An electrically variable capacitor according to the present invention, there is provided circuit including a first node connected to one side of an RF power supply, a second node connected to the other side of the RF power supply, a variable capacitor connected to the first node, a PIN diode connected in parallel with the variable capacitor, a switch connected in series with the PIN diode, and an inductor connected in parallel with the variable capacitor and the switch.

An electrically variable capacitor circuit and a semiconductor processing system including the same of the present invention can reduce the number of elements to save costs and reduce volume, and can have price competitiveness by using relatively inexpensive physical elements.

Further, the configuration of an external circuit can be simplified by reducing the number of active elements, and the application of a high voltage system can be facilitated by minimizing voltage stress on a switch.

### BRIEF DESCRIPTION OF THE DRAWINGS

FIG. 1 is a view for describing a semiconductor processing system according to an embodiment of the present invention.

FIG. 2 is a view for describing an impedance matching circuit including a plurality of electrically variable capacitor circuits according to the embodiment of the present invention.

FIG. 3 is a view for describing a structure of an electrically variable capacitor circuit according to the embodiment of the present invention in detail.

FIG. 4 is a view for describing a structure of an electrically variable capacitor circuit according to another embodiment of the present invention in detail.

FIG. 5 is a view for describing the volumes of various elements applicable to the electrically variable capacitor circuit.

FIGS. 6 to 9 are views for describing an existing electrically variable capacitor circuit.

FIG. 10 is a view for describing the simulation and experimental waveforms of the electrically variable capacitor circuit according to the embodiment of the present invention.

FIG. 11 is a view for describing a capacitance variable time of the electrically variable capacitor circuit according to the embodiment of the present invention.

FIG. 12 is a view for describing voltage stress at a switch of the electrically variable capacitor circuit according to the embodiment of the present invention.

### DETAILED DESCRIPTION

Hereinafter, embodiments of the present invention will be described in detail with reference to the accompanying drawings. First, in the addition of reference numerals to the components of each drawing, it is noted that the same components are given the same reference numerals as much as possible even when the components are shown in different drawings. Further, in the description of the present invention, when it is determined that detailed descriptions of related known components or functions may be obvious to those skilled in the art or obscure the principle of the present invention, the detailed descriptions thereof will be omitted.

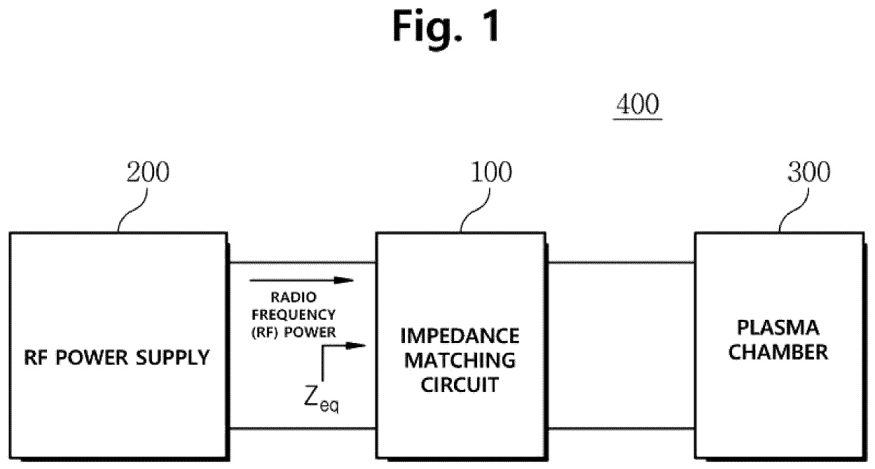

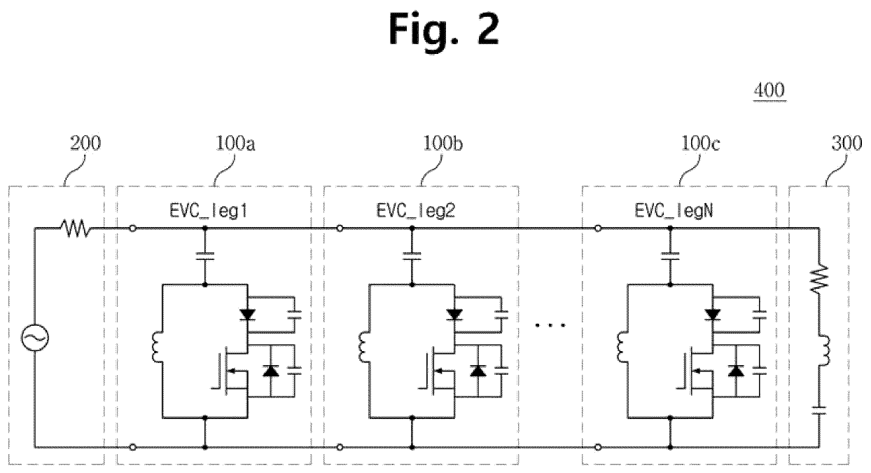

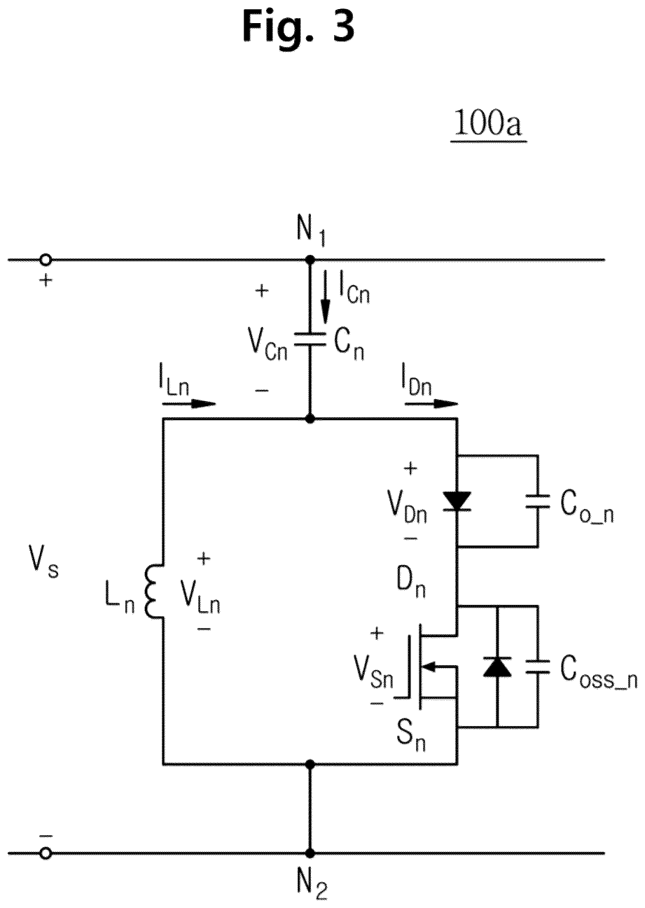

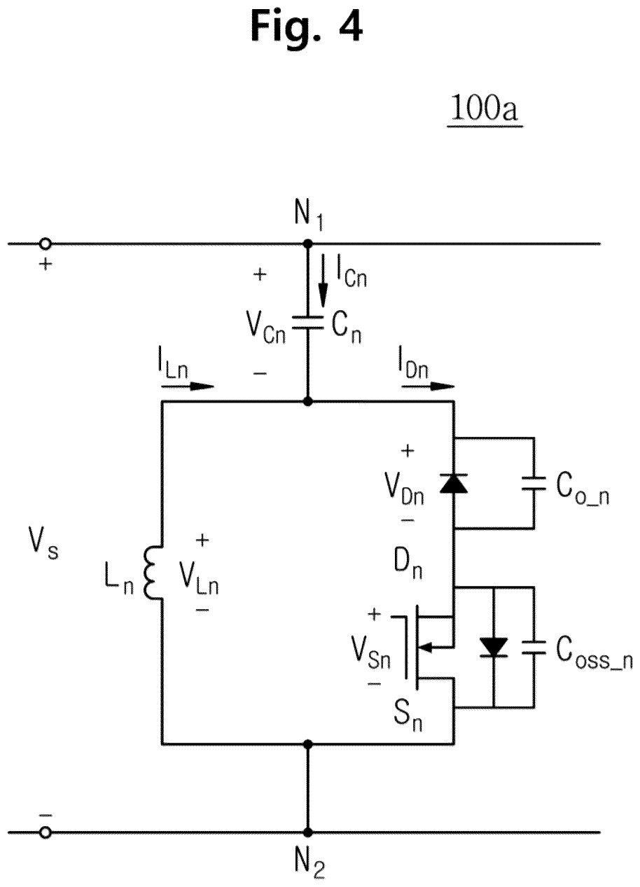

FIG. 1 is a view for describing a semiconductor processing system according to an embodiment of the present invention, FIG. 2 is a view for describing an impedance matching circuit including a plurality of electrically variable capacitor circuits according to the embodiment of the present invention, FIG. 3 is a view for describing a structure of an electrically variable capacitor circuit according to the embodiment of the present invention in detail, and FIG. 4 is a view for describing a structure of an electrically variable capacitor circuit according to another embodiment of the present invention in detail.

Referring to FIGS. 1 to 4, a semiconductor processing system 400 includes an impedance matching circuit 100 including electrically variable capacitor circuits 100a, 100b, and 100c, a radio frequency (RF) power supply 200, and a plasma chamber 300, which is a load.

The RF power supply 200 generates and supplies RF power, and the plasma chamber 300 receives the RF power from the RF power supply 200. The impedance matching circuit is disposed between the RF power supply 200 and the plasma chamber 300 to match output impedance to the plasma chamber 300. For example, when the RF power from the RF power supply 200 is fixed to the system impedance of 50 ohms of the impedance matching circuit 100, the impedance matching circuit 100 may be operated for impedance matching with the plasma chamber 300.

Specifically, the impedance matching circuit 100 may include the plurality of electrically variable capacitor circuits 100a, 100b, and 100c, and the electrically variable capacitor circuits may be respectively divided into leg cells EVC_leg1, EVC_leg2, . . . , and EVC_legN. The plurality of electrically variable capacitor circuits may have the same structure and may be configured of 8 to 28 leg cells, but are not limited thereto.

A first electrically variable capacitor circuit 100a corresponding to a first leg cell EVC_leg1 may include a variable capacitor Cₙ connected in parallel with the RF power supply 200, a PIN diode Dₙ connected in parallel with the variable capacitor Cₙ, a switch Sₙ (for example, a metal-oxide semiconductor field-effect-transistor (MOSFET)) connected in series with the PIN diode Dₙ, and an inductor Lₙ connected in parallel with the variable capacitor Cₙ and the switch Sₙ. The switch Sₙ may be disposed to maintain or disconnect a connection of the PIN diode Dₙ in response to processor control. The semiconductor processing system 400 may further include a gate driver for controlling the switch Sₙ and a processor for controlling the gate driver.

Each of the electrically variable capacitor circuits 100a, 100b, and 100c (hereinafter, described based on the first electrically variable capacitor circuit 100a) in FIG. 3 includes a variable capacitor Cₙ, a PIN diode Dₙ, a switch Sₙ, and an inductor Lₙ disposed between a first node N₁ connected to a first terminal of the RF power supply 200 and a second node N₂ connected to a second terminal of the RF power supply 200. The variable capacitor Cₙ receives an input current I_{Cn} transmitted through the first node N₁. The PIN diode Dₙ is connected in parallel with the variable capacitor Cₙ, and receives an input current I_{Dn} through an anode. The switch Sₙ is connected in series with a cathode of the PIN diode Dₙ. The inductor Lₙ is connected in parallel with the variable capacitor Cₙ and the switch Sₙ.

An electrically variable capacitor circuit 100a in FIG. 4 includes a variable capacitor Cₙ, a PIN diode Dₙ, a switch Sₙ, and an inductor Lₙ disposed between a first node N₁ connected to a first terminal of the RF power supply 200 and a second node N₂ connected to a second terminal of the RF power supply 200. The variable capacitor Cₙ receives an input current I_{Cn} transmitted through the first node N₁. The PIN diode Dₙ is connected in parallel with the variable capacitor Cₙ, and receives an input current I_{Dn} through a cathode. The switch Sₙ is connected in series with an anode of the PIN diode Dₙ. The inductor Lₙ is connected in parallel with the variable capacitor Cₙ and the switch Sₙ.

In the electrically variable capacitor circuit 100a having the above-described structure, the input current I_{Cn} is supplied through the first node N₁ when positive (+) power among alternating current (AC) power is supplied from the RF power supply 200, and an inductor current I_{Ln} may flow in the inductor Lₙ and a switch current I_{Sn} may flow in the switch Sₙ when negative (−) power among the alternating current power is supplied.

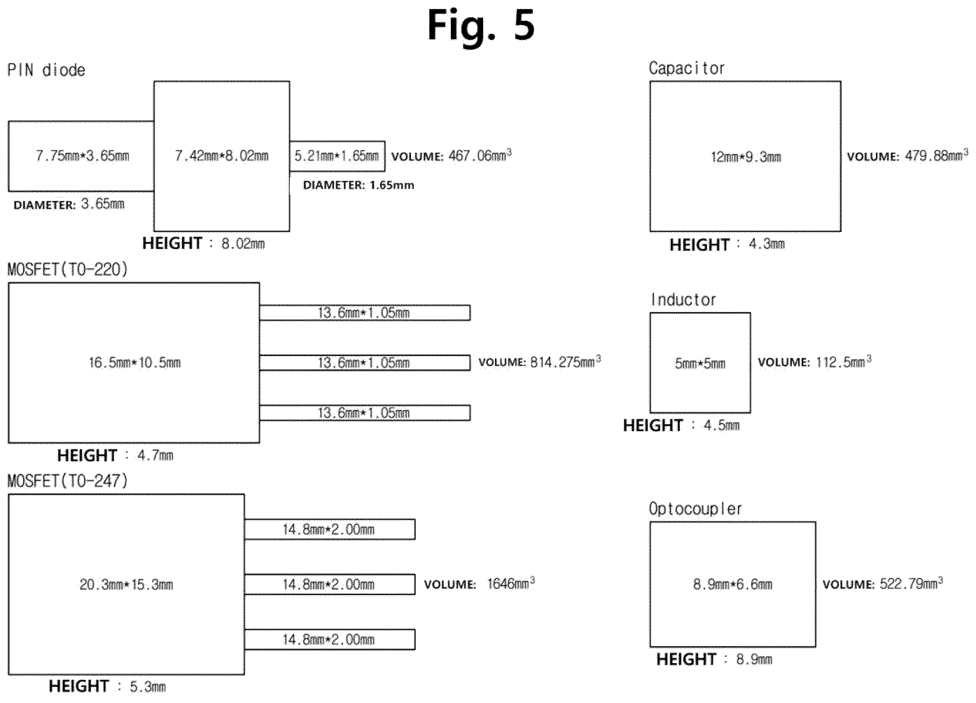

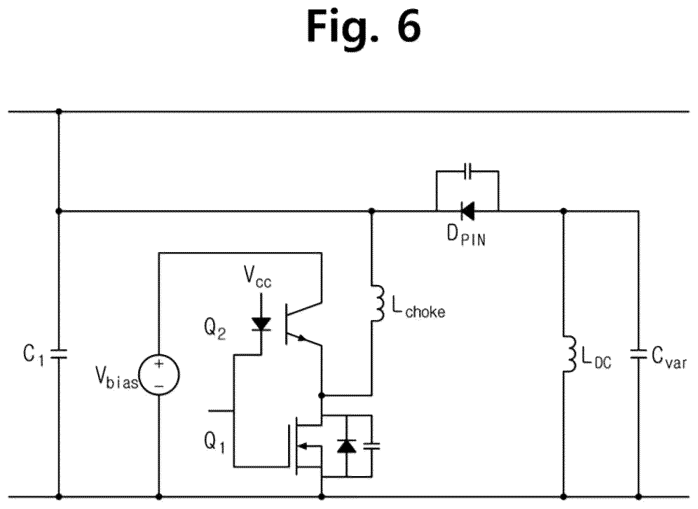

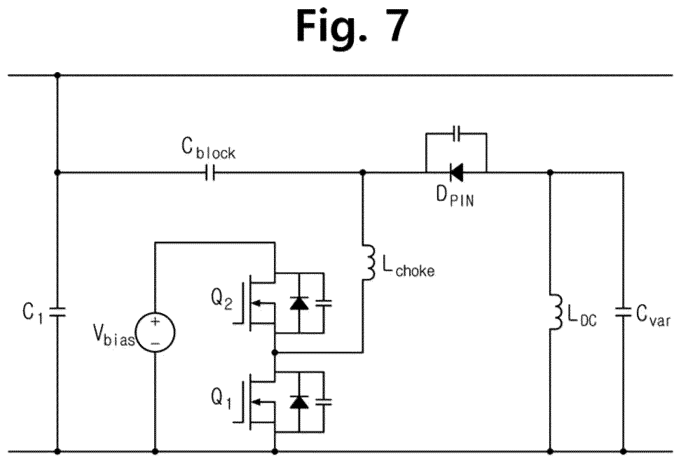

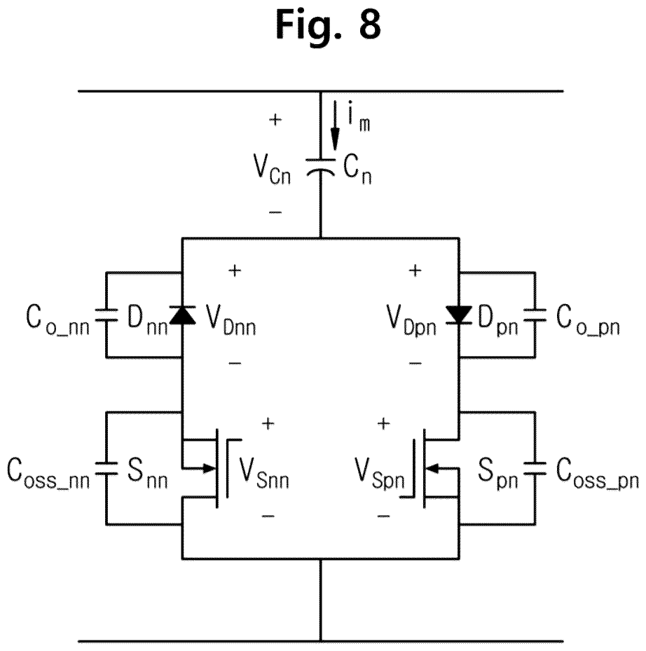

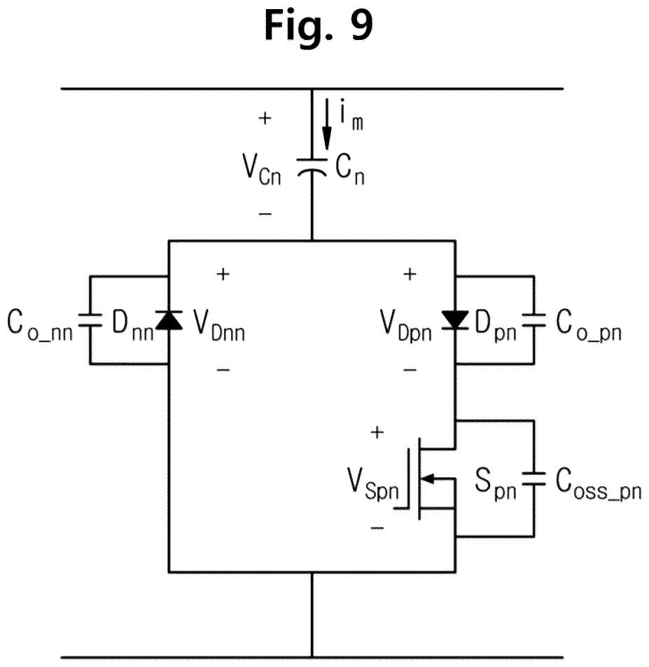

FIG. 5 is a view for describing the volumes of various elements applicable to the electrically variable capacitor circuit, and FIGS. 6 to 9 are views for describing an existing electrically variable capacitor circuit. FIG. 6 is a view illustrating an optocoupler variable capacitor circuit, FIG. 7 is a view illustrating a half-bridge variable capacitor circuit, FIG. 8 is a view illustrating a bidirectional variable capacitor circuit, and FIG. 9 is a view illustrating a unidirectional variable capacitor circuit.

Referring to FIGS. 3 to 9, the PIN diode may have a volume of 467.06 (mm³, hereinafter, units will be omitted), a first type switch (for example, MOSFET, TO-220) may have a size of 814.275, and a second type switch (for example, MOSFET, TO-247) may have a size of 1646. A volume of the variable capacitor may be 479.88, a volume of the inductor may be 112.5, and a volume of an optocoupler may be 522.79.

Hereinafter, the existing electrically variable capacitor circuit and the electrically variable capacitor circuit 100a of the present invention are compared, and characteristics of each electrically variable capacitor circuit are shown in [Table 1].

TABLE 1

| | | Components | Voltage | | | |
|---|---|---|---|---|---|---|
| | Essential | required for | stress of | | | |
| Classification | items | expansion | switch | | Costs | Capacity |
| Optocoupler | External | S: 2 ea, D: 1 ea | 1.3 | V_{Peak} | X | X |
| | power | L: 2 ea C: 1 a | | | | |
| | source | | | | | |
| Half-bridge | External | S: 2 ea, D: 1 ea | 2 | V_{Peak} | X | X |
| | power | L: 2 ea C: 1 ea | | | | |
| | source | | | | | |
| Bidirectional | | S: 2 ea, D: 2 ea | | V_{Peak} | High | Low |
| | | C: 1ea | | | | |
| Unidirectional | | S: 1 ea, D: 2 ea | 1.3 | V_{Peak} | X | X |
| | | C: 1 ea | | | | |
| The present | | S: 1 ea, D: 1 ea | | V_{Peak} | Low | High |

| | |
|---|---|
| invention | L: 1 ea C: 1 ea |

The optocoupler electrically variable capacitor circuit may include a fixed capacitor C₁, a bias power source V_{bias}, a constant voltage source V_{cc}, a first switch Q₁ and a second switch Q₂, a choke inductor L_{choke} of which one side is connected between the first switch Q₁ and the second switch Q₂, a direct current (DC) inductor L_{DC} connected in parallel with the choke inductor L_{choke}, a variable capacitor Cᵥₐᵣ connected in parallel with the DC inductor L_{DC}, and a PIN diode D_{PIN} disposed between the other side of the inductor L_{choke} and the DC inductor L_{DC}. Since the optocoupler electrically variable capacitor circuit has a bias power source V_{bias} volume (for example, 13968 mm³, hereinafter, units will be omitted), a volume of a switching-related active element is 2635, volumes of a gate driver and a power stage are 2000, and volumes of other passive elements are 705, a volume which is changed according to a change in the number of capacitors may become 5340. When N capacitors are connected, the volume of the optocoupler electrically variable capacitor circuit has a size in which the bias power source V_{bias} size is set to a default (13968) and an N capacitor circuit volume (for example, N×5340) is added.

The half-bridge electrically variable capacitor circuit may include a fixed capacitor C₁, a bias power source V_{bias}, a first switch Q₁ and a second switch Q₂, a choke inductor L_{choke} of which one side is connected between the first switch Q₁ and the second switch Q₂, a direct current (DC) inductor L_{DC} connected in parallel with the choke inductor L_{choke}, a variable capacitor Cᵥₐᵣ connected in parallel with the DC inductor L_{DC}, a PIN diode D_{PIN} disposed between the other side of the inductor L_{choke} and the DC inductor L_{DC}, and a block capacitor C_{block} connected in series with the PIN diode D_{PIN} and connected in parallel with the fixed capacitor C₁. Since the half-bridge electrically variable capacitor circuit has a bias power source V_{bias} volume (for example, 13968 mm³, hereinafter, units will be omitted), a volume of a switching-related active element is 3759, volumes of a gate driver and a power stage are 4000, and volumes of other passive elements are 1184, a volume which is changed according to an increase of capacitors may become 8943. When N capacitors are connected, the volume of the half-bridge electrically variable capacitor circuit has a size in which the bias power source V_{bias} size is set to a default (13968) and an N capacitor circuit volume (for example, N×8943) is added.

The bidirectional electrically variable capacitor circuit may include a fixed capacitor Cₙ, a first directional diode Dₙₙ, a second directional diode Dₚₙ connected in parallel with the first directional diode Dₙₙ, a first switch Sₙₙ connected in series with the first directional diode Dₙₙ, a second switch Sₚₙ connected in series with the second directional diode Dₚₙ, a first diode capacitor D_{o_nn} connected in parallel with the first directional diode Dₙₙ, a second diode capacitor D_{o_pn} connected in parallel with the second directional diode Dₚₙ, a first switch capacitor C_{oss_nn} connected in parallel with the first switch Sₙₙ, and a second switch capacitor C_{oss_pn} connected in parallel with the second switch Sₚₙ. Since the bidirectional electrically variable capacitor circuit of this structure does not include a separate bias power source V_{bias}, there is no volume increase due to the bias power source, and since a volume of a switching-related active element is 4226, volumes of a gate driver and a power stage are 4000, and volumes of other passive elements are 480, a volume which is changed according to an increase of capacitors may become 8706. When N capacitors are connected, the volume of the bidirectional electrically variable capacitor circuit has a size in which an N capacitor circuit volume (for example, N×8706) is added.

The unidirectional electrically variable capacitor circuit may include a fixed capacitor Cₙ, a first directional diode Dₙₙ, a second directional diode Dₚₙ connected in parallel with the first directional diode Dₙₙ, a second switch Sₚₙ connected in series with the second directional diode Dₚₙ, a first diode capacitor D_{o_nn} connected in parallel with the first directional diode Dₙₙ, a second diode capacitor D_{o_pn} connected in parallel with the second directional diode Dₚₙ, and a second switch capacitor C_{oss_pn} connected in parallel with the second switch Sₚₙ. Since the unidirectional electrically variable capacitor circuit of this structure does not include a separate bias power source V_{bias}, and structures of the switch and the switch capacitors are excluded compared to the bidirectional electrically variable capacitor circuit, a volume which is changed according to an increase of capacitors may become 5060. When N capacitors are connected, the volume of the bidirectional electrically variable capacitor circuit has a size in which an N capacitor circuit volume (for example, N×5060) is added.

Meanwhile, as the electrically variable capacitor circuit 100a of the present invention does not use a separate power stage, a basic power stage volume is not included, and since the switching-related active element has a size of 2133 (mm³, hereinafter, units will be omitted), the gate driver and the power stage have a size of 2000, and other passive elements have a size of 480, when N capacitors are connected, a size of N×4613 is added to the volume. Accordingly, it can be seen that the electrically variable capacitor circuit 100a of the present invention has the relatively smallest volume.

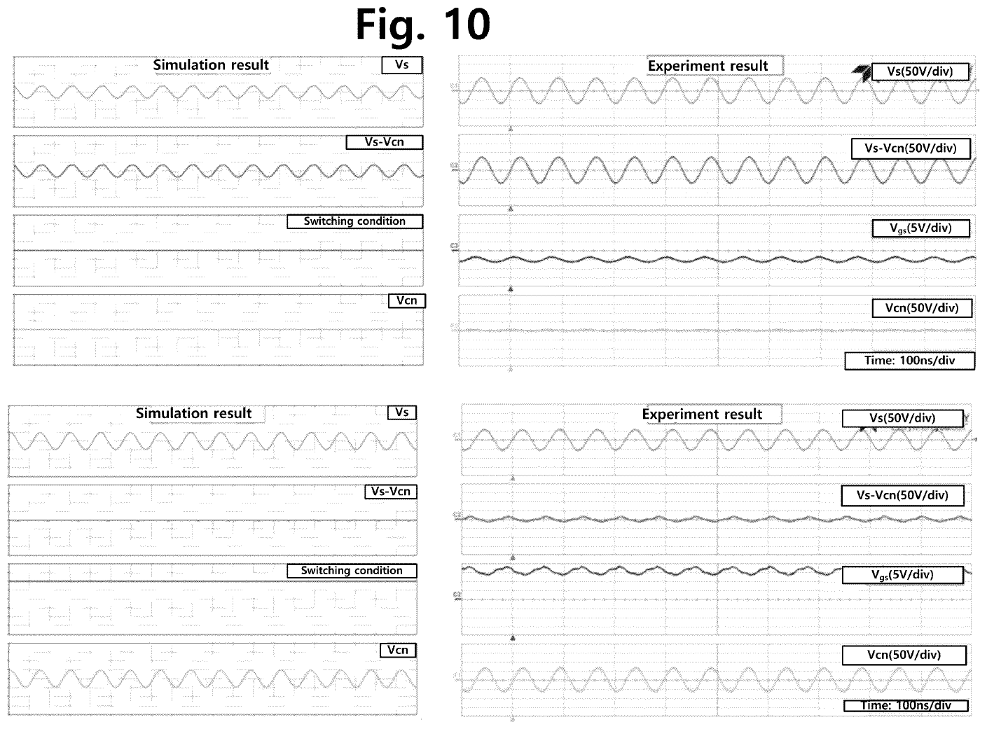

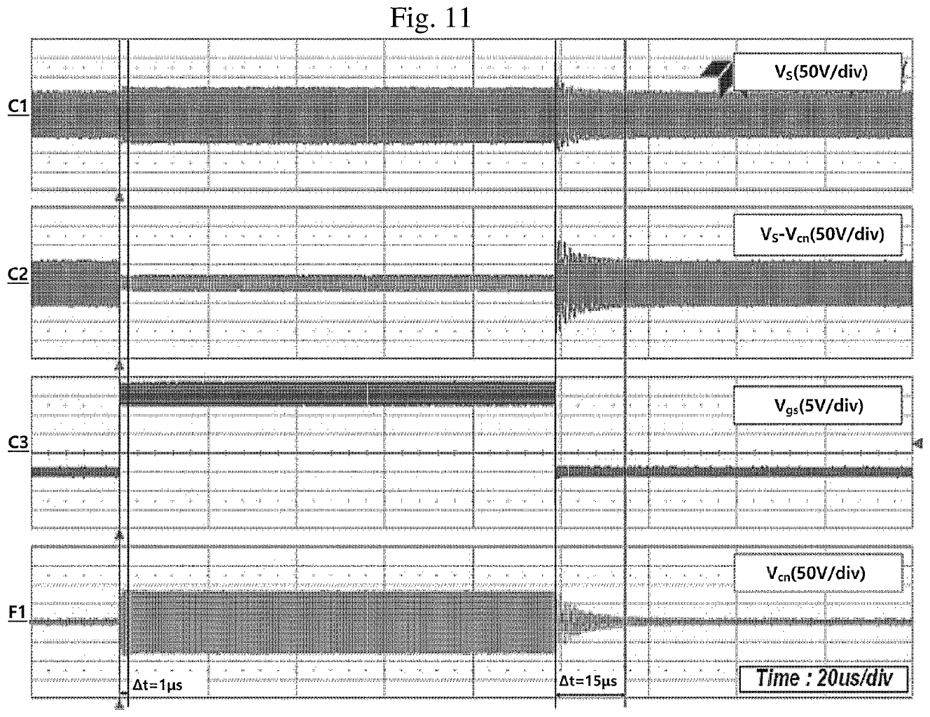

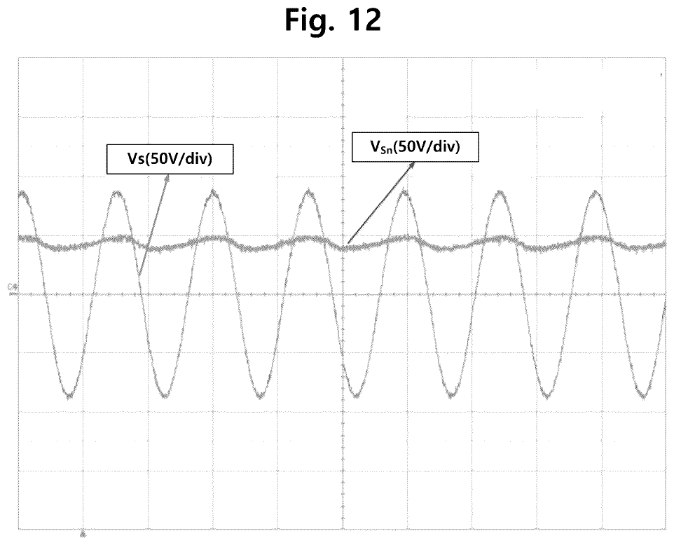

FIG. 10 is a view for describing the simulation and experimental waveforms of the electrically variable capacitor circuit according to the embodiment of the present invention, FIG. 11 is a view for describing a capacitance variable time of the electrically variable capacitor circuit according to the embodiment of the present invention, and FIG. 12 is a view for describing voltage stress at a switch of the electrically variable capacitor circuit according to the embodiment of the present invention.

Referring to FIGS. 10 to 12, in the electrically variable capacitor circuit 100a, it can be seen that the waveform in the simulation (ideal waveform) and the waveform acquired through the actual experiment are similar.

Specifically, in the electrically variable capacitor circuit 100a, as a capacitance variable time is shortened, it can be seen that an impedance matching time is reduced, and voltage stress at the switch is low.

Although the preferable embodiments for exemplifying the technical spirit of the present invention were described and illustrated above, the present invention is not limited to the configurations and actions as shown and described above, and those skilled in the art should understand that many changes and modifications may be made to the present invention without departing from the scope of the technical spirit. Accordingly, all those appropriate changes, modifications, and equivalents should be considered as belonging to the scope of the present invention.

1. A semiconductor processing system comprising:
a radio frequency (RF) power supply configured to generate and supply RF power;
a plasma chamber configured to receive the RF power from the RF power supply; and
an impedance matching circuit disposed between the RF power supply and the plasma chamber to match output impedance to the plasma chamber,
wherein the impedance matching circuit includes a plurality of electrically variable capacitor circuits, and
each of the electrically variable capacitor circuits includes a first node connected to one side of the RF power supply, a second node connected to the other side of the RF power supply, a variable capacitor connected to the first node, a PIN diode connected in parallel with the variable capacitor, a switch connected in series with the PIN diode, and an inductor connected in parallel with the variable capacitor and the switch.

2. The semiconductor processing system of claim 1, wherein the plurality of electrically variable capacitor circuits have the same structure.

3. The semiconductor processing system of claim 1, wherein the number of the plurality of electrically variable capacitor circuits is configured to be 8 to 28.

4. The semiconductor processing system of claim 1, wherein:
an anode of the PIN diode is connected to the variable capacitor; and
a cathode of the PIN diode is connected to the switch.

5. The semiconductor processing system of claim 1, wherein:
a cathode of the PIN diode is connected to the variable capacitor; and
an anode of the PIN diode is connected to the switch.

6. An electrically variable capacitor circuit comprising:
a first node connected to one side of an RF power supply;
a second node connected to the other side of the RF power supply;
a variable capacitor connected to the first node;
a PIN diode connected in parallel with the variable capacitor,
a switch connected in series with the PIN diode; and
an inductor connected in parallel with the variable capacitor and the switch.
